(19) United States
(12) Patent Application Publication
(10) Pub. No.: US 2026/0213489 A1
(43) Pub. Date: Jul. 23, 2026

(54) LIGHT-EMITTING DEVICE AND LIGHT-EMITTING MODULE

(71) Applicant: STANLEY ELECTRIC CO., LTD., Tokyo (JP)

(72) Inventors: Hiroyuki KASHIWAGI, Tokyo-to (JP); Ayumu HIGASHIDA, Tokyo-to (JP)

(73) Assignee: STANLEY ELECTRIC CO., LTD., Tokyo (JP)

(21) Appl. No.: 19/448,010

(22) Filed: Jan. 13, 2026

(30) Foreign Application Priority Data
Jan. 17, 2025 (JP) 2025-006812

(51) Int. Cl. H01S 5/02255; H01S 5/02257; H01S 5/02315; H01S 5/183; H01S 5/30

(52) U.S. Cl. CPC H01S 5/02255; H01S 5/02257; H01S 5/02315; H01S 5/183; H01S 5/3013

(57) ABSTRACT

Provided is a light-emitting device capable of controlling output of an emitted light from a vertical-cavity light-emitting element without degrading utilization efficiency of the emitted light, and a light-emitting module including the light-emitting device. The light-emitting device includes a substrate having a recess, a vertical-cavity light-emitting element, a photodetector, a transmissive plate, and a light-reflecting structure. The vertical-cavity light-emitting element is mounted on a bottom surface of the recess of the substrate and includes a group III-nitride semiconductor and emits a laser light toward an opening of the recess. The laser light includes a main light forming a beam spot and a secondary light. The secondary light is emitted in a direction different from the main light and has a lower light output than the main light. The photodetector is mounted on a bottom surface of the recess of the substrate. The transmissive plate seals an opening of the recess. The light-reflecting structure is formed in a region of the transmissive plate. The region is other than a main light incident region as a region where the main light is incident.

### BACKGROUND

### 1. Technical Field

The present invention relates to a light-emitting device including a vertical-cavity light-emitting element and a light-emitting module including the light-emitting device.

### 2. Description of the Related Art

A light-emitting device including a vertical-cavity light-emitting element is known. For example, Japanese Patent No. 7318180 discloses a lighting device including a light source package, which includes a substrate, a light source unit including a vertical-cavity light-emitting element, a photodetector, and a plate-shaped cover member; and a light-emission control unit configured to control light emission of the light source unit.

### SUMMARY

In a lighting device disclosed in Japanese Patent No. 7318180, a reflective film is formed on a cover member across a region excluding a region directly above the light source unit. Part of the light emitted from the light source unit is reflected by the reflective film and received by the photodetector. When the received light is outside a predetermined intensity range, the light-emission control unit stops the light emitted from the light source unit, assuming that the cover member has been detached or damaged.

In the lighting device disclosed in Japanese Patent No. 7318180, a vertical-cavity surface-emitting laser (VCSEL) is used as the light source, and it is suggested that all light-emitting points emit substantially the same amount of light simultaneously, thereby providing a surface light source. In this case, even though all of the light emitted from the light source is originally intended to be emitted outside, some of the light is reflected by the reflective film, which may reduce the output of the light emitted outside. To compensate for this reduction in output, for example, the area of the package must be increased or more current must be applied to the light source.

In the lighting device of Japanese Patent No. 7318180, for example, when a light-emitting diode (LED) is used as the light source, its light distribution characteristics can result in significant stray light, which may reduce the utilization efficiency of light emitted from the lighting device.

It is an object of the present invention, made in view of the foregoing, to provide a light-emitting device capable of controlling output of emitted light from a vertical-cavity light-emitting element without degrading the utilization efficiency of the emitted light, and a light-emitting module including the light-emitting device.

A light-emitting device according to the present invention includes a substrate having a recess, a vertical-cavity light-emitting element, a photodetector, a transmissive plate, and a light-reflecting structure. The vertical-cavity light-emitting element is mounted on a bottom surface of the recess of the substrate and includes a group III-nitride semiconductor. The vertical-cavity light-emitting element emits a laser light toward an opening of the recess. The laser light includes a main light forming a beam spot and a secondary light. The secondary light is emitted in a direction different from the main light and has a lower light output than the main light. The photodetector is mounted on a bottom surface of the recess of the substrate. The transmissive plate seals an opening of the recess. The light-reflecting structure is formed in a region of the transmissive plate. The region is other than a main light incident region as a region where the main light is incident.

A light-emitting module according to the present invention includes a light-emitting device and an output control unit. The light-emitting device includes a substrate having a recess, a vertical-cavity light-emitting element, a photodetector, a transmissive plate, and a light-reflecting structure. The vertical-cavity light-emitting element is mounted on a bottom surface of the recess of the substrate and includes a group III-nitride semiconductor. The vertical-cavity light-emitting element emits a laser light toward an opening of the recess. The laser light includes a main light forming a beam spot and a secondary light. The secondary light is emitted in a direction different from the main light and has a lower light output than the main light. The photodetector is mounted on a bottom surface of the recess of the substrate. The transmissive plate seals an opening of the recess. The light-reflecting structure is formed in a region of the transmissive plate. The region is other than a main light incident region as a region where the main light is incident. The output control unit is electrically connected to each of the vertical-cavity light-emitting element and the photodetector and capable of controlling an output of a laser light of the vertical-cavity light-emitting element. The output control unit controls the output of the laser light of the vertical-cavity light-emitting element in accordance with a light intensity received by the photodetector.

### BRIEF DESCRIPTION OF THE DRAWINGS

FIG. 1 is a top view of a light-emitting device according to Embodiment 1;

FIG. 2 is a cross-sectional view of the light-emitting device according to Embodiment 1;

FIG. 3 is a perspective view of a vertical-cavity surface-emitting laser according to Embodiment 1;

FIG. 4 is a top view of the vertical-cavity surface-emitting laser according to Embodiment 1;

FIG. 5 is a cross-sectional view of the vertical-cavity surface-emitting laser according to Embodiment 1;

FIG. 6 is a graph showing the relationship between the emission angle and the output of light emitted from the vertical-cavity surface-emitting laser of the light-emitting device according to Embodiment 1;

FIG. 7 is a block diagram illustrating a configuration of a light-emitting module as an exemplary application of the light-emitting device according to Embodiment 1;

FIG. 8 is a top view of a light-emitting device according to a modification of Embodiment 1;

FIG. 9 is a top view of a light-emitting device according to a modification of Embodiment 1;

FIG. 10 is a top view of a light-emitting device according to a modification of Embodiment 1; and

FIG. 11 is a cross-sectional view of a light-emitting device according to Embodiment 2.

### DETAILED DESCRIPTION

Hereinafter, embodiments of the present invention will be described in detail with reference to the drawings. In the drawings, the same reference numerals are assigned to like components, and redundant descriptions of like components are omitted.

### Embodiment 1

### Configuration of Light-emitting Device 100

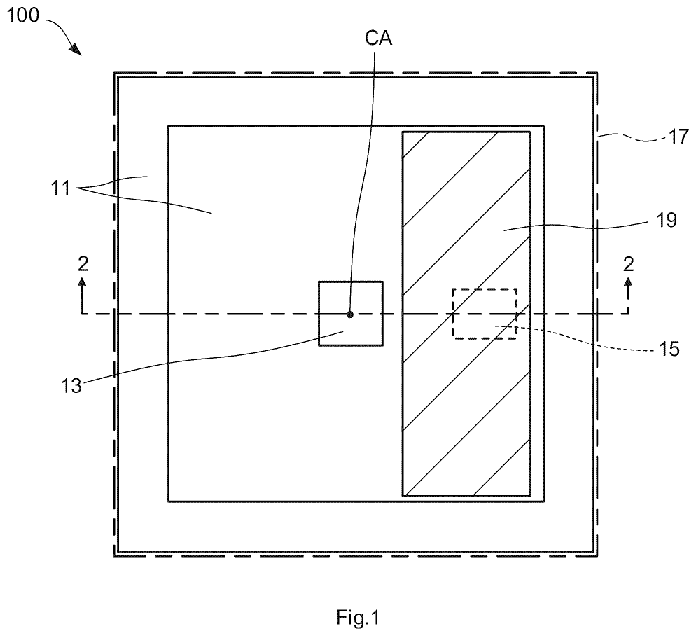

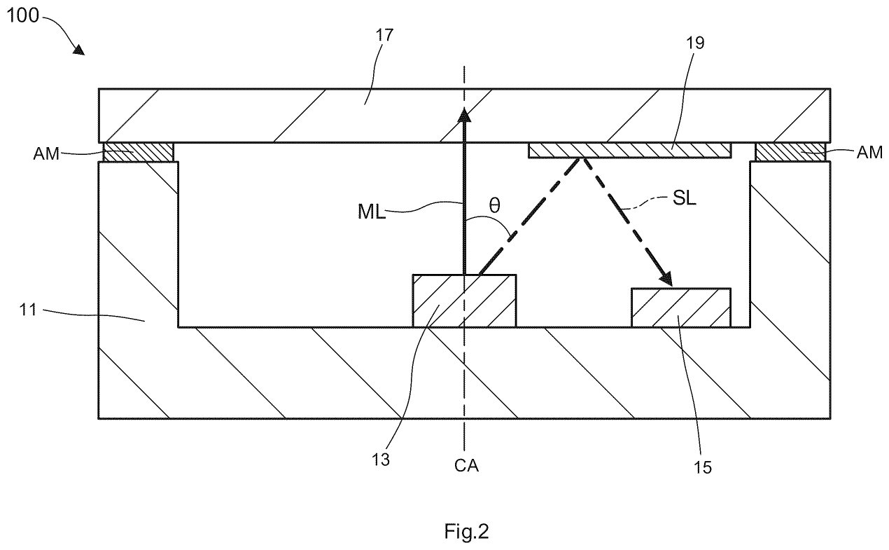

First, a configuration of a light-emitting device 100 according to the present embodiment will be described with reference to FIG. 1 and FIG. 2. FIG. 1 is a top view of the light-emitting device 100. Also, FIG. 2 is a cross-sectional view of the light-emitting device 100 taken along the line 2-2 of FIG. 1. In FIG. 2, the vertical direction in the figure is the height direction of the light-emitting device 100.

The light-emitting device 100 includes a substrate 11, a vertical-cavity surface-emitting laser 13 constituted of a Group III-nitride semiconductor (hereinafter referred to as the surface-emitting laser 13), a photodetector 15, a transmissive plate 17, and a light-reflecting structure 19. In FIG. 1, only the outline of the transmissive plate 17 is illustrated by a one-dot chain line to avoid complication of the illustration, and the hatching is applied to the light-reflecting structure 19. In FIG. 1, the adhesive member AM is omitted.

### Substrate 11

A substrate 11 is an insulating substrate having a rectangular top-surface shape. The substrate 11 has, in a central region of a top surface, a recess having a rectangular bottom surface and an opening toward an upper side. In other words, the substrate 11 has a flat plate-like bottom portion and a frame portion formed along an outer edge of the bottom portion.

In the light-emitting device 100 of this embodiment, the substrate 11 is made of a ceramic such as aluminum nitride (AlN). The substrate 11 may be integrally formed to include a recess, or may be formed by joining a flat plate-like bottom and a frame-shaped portion with an adhesive member.

### Surface-Emitting Laser 13

The surface-emitting laser 13 is a vertical-cavity surface-emitting laser (VCSEL) made of a Group III-nitride semiconductor, has a rectangular top-surface shape, and is mounted on a wiring electrode (not illustrated) provided on a bottom surface of a recess of the substrate 11.

The surface-emitting laser 13 is configured to receive power from outside the substrate 11 via the above-described wiring electrode, a through-hole electrode (not illustrated) that is connected to the wiring electrode and penetrates a bottom portion of the substrate 11, and a mounting electrode (not illustrated) that is connected to the through-hole electrode and provided on the bottom surface of the substrate 11. Alternatively, a configuration may be adopted in which the surface-emitting laser 13 is mounted on a submount substrate (not illustrated). In other words, a submount substrate may be disposed between the substrate 11 and the surface-emitting laser 13.

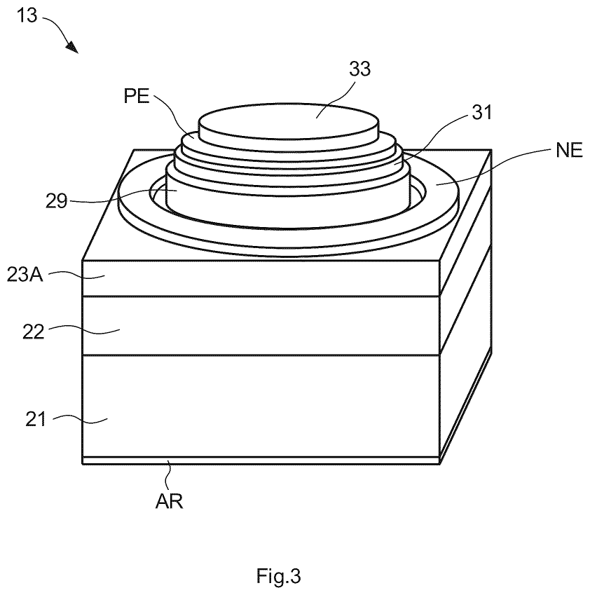

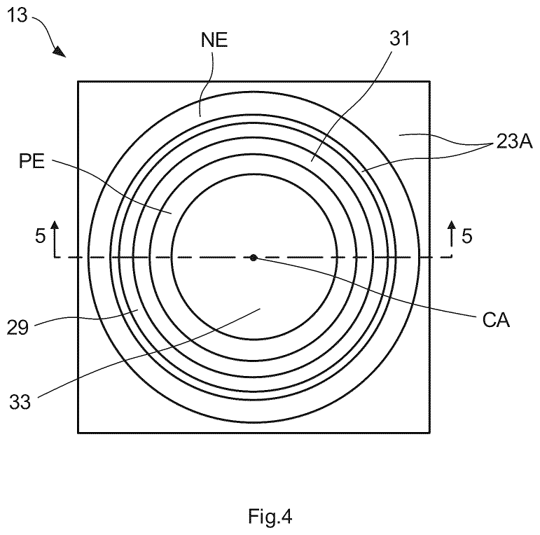

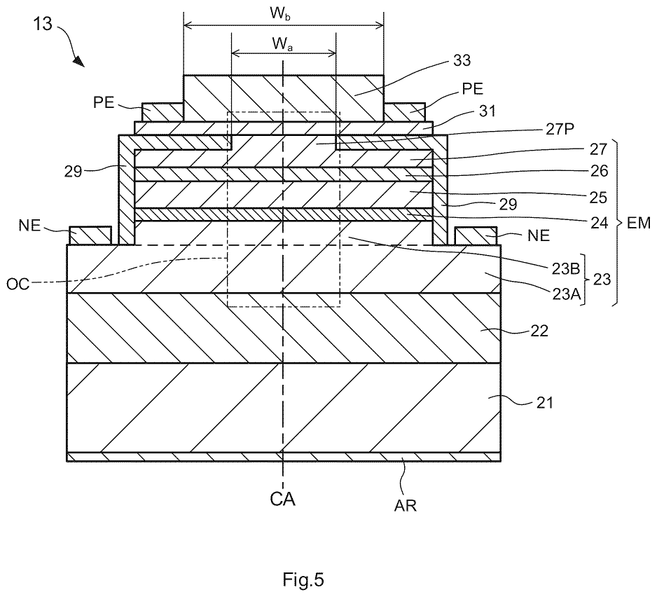

The detailed configuration of the surface-emitting laser 13 will now be described with reference to FIGS. 3 to 5. FIG. 3 is a perspective view of the surface-emitting laser 13. FIG. 4 is a top view of the surface-emitting laser 13. FIG. 5 is a cross-sectional view taken along the line 5-5 of the surface-emitting laser 13 illustrated in FIG. 4. In FIG. 5, the vertical direction in the figure is the height direction of the surface-emitting laser 13.

The surface-emitting laser 13 includes a transparent substrate 21, a first multilayer reflector 22, a semiconductor structure layer EM, an insulating layer 29, a conductive film 31, and a second multilayer reflector 33. In the light-emitting device 100, the surface-emitting laser 13 is mounted in a recess of the substrate 11 in an upside-down orientation relative to the state illustrated in FIG. 5. That is, the surface-emitting laser 13 is mounted such that a top surface of the second multilayer reflector 33 illustrated in FIG. 5 faces the bottom surface of the recess of the substrate 11.

The transparent substrate 21 is a flat plate-like transparent substrate having a rectangular top-surface shape. The transparent substrate 21 is also a growth substrate on whose top surface semiconductor crystals can be grown. The transparent substrate 21 is made of a material that is transmissive to light having a blue wavelength, such as undoped gallium nitride (GaN).

Hereinafter, an axis that passes through the center of a top surface of the transparent substrate 21 of the surface-emitting laser 13 and is perpendicular to the top surface will be referred to as a central axis CA. Furthermore, a direction away from the central axis CA in a radial direction is described as an outward direction.

The first multilayer reflector 22 is a semiconductor multilayer reflector constituted of semiconductor layers grown on the top surface of the transparent substrate 21. The first multilayer reflector 22 is a so-called distributed Bragg reflector (DBR) in which, on the top surface of the transparent substrate 21, a semiconductor layer having a relatively high refractive index and a semiconductor layer having a refractive index lower than that of the high refractive index semiconductor layer are alternately stacked.

The first multilayer reflector 22 is formed, for example, by stacking, on the top surface of the transparent substrate 21, 42 pairs of high refractive index semiconductor films made of GaN and low-refractive-index semiconductor films made of aluminum indium nitride (AlInN). With this configuration, the first multilayer reflector 22 exhibits reflectivity for a light in the blue wavelength range. A buffer layer (not illustrated) made of GaN is provided between the transparent substrate 21 and the first multilayer reflector 22.

The semiconductor structure layer EM is a stacked structure constituted of a plurality of semiconductor layers formed on the first multilayer reflector 22. The semiconductor structure layer EM includes an n-type semiconductor layer 23 formed on the first multilayer reflector 22, a light-emitting layer 24 formed on the n-type semiconductor layer 23, an intermediate layer 25 formed on the light-emitting layer 24, an electron blocking layer 26 formed on the intermediate layer 25, and a p-type semiconductor layer 27 formed on the electron blocking layer 26.

The n-type semiconductor layer 23, as the first semiconductor layer of the first conductivity type, is a semiconductor layer formed over a top surface of the first multilayer reflector 22. The n-type semiconductor layer 23 is made of GaN and doped with silicon (Si) as an n-type impurity.

The n-type semiconductor layer 23 has a structure of a so-called mesa shape, constituted of a flat plate-like lower portion 23A and a cylindrical upper portion 23B that protrudes upward along the central axis CA from the center of the lower portion 23A (see FIG. 5).

The light-emitting layer 24 is formed to extend across a top surface of the upper portion 23B of the n-type semiconductor layer 23, and is a semiconductor layer having a quantum well structure in which a well layer made of indium gallium nitride (InGaN) and a barrier layer made of GaN are alternately stacked.

The light-emitting layer 24 is formed such that its light-emitting center lies on the central axis CA. The light-emitting layer 24 emits a blue light with a peak wavelength of 445 nm, for example. In the surface-emitting laser 13 according to this embodiment, a thickness of a well layer constituting the light-emitting layer 24 is 4 nm, and a thickness of the barrier layer is 3 nm.

The intermediate layer 25 is a semiconductor layer constituted of undoped GaN that is formed on a well layer formed at an uppermost portion of the light-emitting layer 24. That is, the intermediate layer 25 can be considered the final barrier layer of the light-emitting layer 24. In the surface-emitting laser 13 of this embodiment, the intermediate layer 25 has a thickness of 120 nm.

The intermediate layer 25 functions as a layer that suppresses p-type impurities from diffusing from the electron blocking layer 26, which is formed on the intermediate layer 25, to the light-emitting layer 24. In addition to GaN, undoped InGaN or AlGaN may be used as a material for the intermediate layer 25.

The electron blocking layer (EBL) 26 is formed over a top surface of the intermediate layer 25 and is a semiconductor layer made of GaN doped with magnesium (Mg) as a p-type impurity. The electron blocking layer 26 functions as a layer that suppresses overflow, toward the p-type semiconductor layer 27 side, of the electrons injected from the n-type semiconductor layer 23 into the light-emitting layer 24.

The p-type semiconductor layer 27, as the second semiconductor layer with the second conductivity type, is a semiconductor layer formed over a top surface of the electron blocking layer 26. The p-type semiconductor layer 27 is constituted of AlGaN and is doped with Mg as a p-type impurity.

As illustrated in FIG. 5, the p-type semiconductor layer 27 has, in a region including the central axis CA of the central portion of the top surface, a protrusion 27P that has a circular top-surface shape and protrudes upward. In other words, in the p-type semiconductor layer 27, a circular annular outer region located outside the circular central region at the center of the top surface is recessed below the central region.

The insulating layer 29 is a coating layer that provides electrical insulation, annularly formed in a region along an outer edge of the protrusion 27P on a top surface of the p-type semiconductor layer 27. The insulating layer 29 covers the top surface of the p-type semiconductor layer 27 such that only the top surface of the protrusion 27P is exposed.

The insulating layer 29 continuously covers, from the top surface of the p-type semiconductor layer 27, a side surface of the p-type semiconductor layer 27, a side surface of the electron blocking layer 26, a side surface of the intermediate layer 25, a side surface of the light-emitting layer 24, and a side surface of the upper portion 23B, while its edge reaches a top surface of the lower portion 23A. In other words, side surfaces of the semiconductor structure layer EM are covered by the insulating layer 29, except at the lower portion 23A of the n-type semiconductor layer 23. Note that the insulating layer 29 may be disposed in a manner to cover the top surface and/or the side surfaces of the lower portion 23A of the n-type semiconductor layer 23, except for a formation region of the n-type electrode NE.

The insulating layer 29 is formed of a material that is transmissive to the blue light and has a refractive index lower than that of the p-type semiconductor layer 27, for example, silicon dioxide (SiO₂). The refractive index of the p-type semiconductor layer 27 made of AlGaN used in the surface-emitting laser 13 of this embodiment is approximately 2.5, and the refractive index of the insulating layer 29 made of SiO₂ is approximately 1.5.

The conductive film 31 is a transparent conductive film having transmissive and conductive properties that is in contact with and covers the top surface of the protrusion 27P of the p-type semiconductor layer 27, while covering the insulating layer 29 over the region surrounding the protrusion 27P of the p-type semiconductor layer 27.

The conductive film 31 is formed of a metal oxide, such as indium tin oxide (ITO) or indium zinc oxide (IZO), which is transmissive to the blue light emitted from the light-emitting layer 24 of the above-described semiconductor structure layer EM. In the surface-emitting laser 13 of this embodiment, a thickness of the conductive film 31 is set to 20 nm.

The n-type electrode NE is a metal electrode formed on the top surface of the lower portion 23A of the n-type semiconductor layer 23 and having a circular annular top-surface shape. The n-type electrode NE, for example, is formed by stacking titanium (Ti) and aluminum (Al) in this order on the top surface of the lower portion 23A.

The p-type electrode PE is a metal electrode made of gold (Au), formed on a top surface of the conductive film 31 and having a circular annular top-surface shape. The p-electrode PE is electrically connected to the p-type semiconductor layer 27 through the conductive film 31.

The second multilayer reflector 33 is a cylindrical dielectric multilayer reflector constituted of dielectric layers deposited on the conductive film 31. The second multilayer reflector 33 is formed so as to contact an inner surface of the p-type electrode PE. That is, a diameter of the second multilayer reflector 33 is an opening diameter of the p-type electrode PE.

The second multilayer reflector 33 is a so-called distributed Bragg reflector (DBR), constituted of alternating layers of a high refractive index dielectric film with a relatively high refractive index and a low refractive index dielectric film with a lower refractive index than the high refractive index dielectric film on the top surface of the conductive film 31.

The second multilayer reflector 33 is formed, for example, on the top surface of the conductive film 31 by stacking 10.5 pairs of high refractive index dielectric films made of niobium pentoxide (Nb₂O₅) and low refractive index dielectric films made of SiO₂. With such a configuration, the second multilayer reflector 33 has a reflectivity with respect to the blue light emitted from the light-emitting layer 24.

A transparent dielectric layer (not illustrated) with a circular top-surface shape may be formed between the second multilayer reflector 33 and the conductive film 31, for example, as a phase adjustment layer. The dielectric layer is constituted of, for example, Nb₂O₅, tantalum pentoxide (Ta₂O₅), zirconium oxide (ZrO₂), titanium oxide (TiO₂), hafnium oxide (HfO₂), and the like.

In the surface-emitting laser 13 of this embodiment, a diameter Wₐ of the top surface of the protrusion 27P of the p-type semiconductor layer 27 is smaller than a diameter W_{b} of the top surface of the second multilayer reflector 33 (see FIG. 5). In other words, the outer edge of the protrusion 27P is located inside the outer edge of the second multilayer reflector 33 in the top view of the surface-emitting laser 13. In the surface-emitting laser 13 of this embodiment, the diameter Wₐ is 5 μm and the diameter W_{b} is 11 μm.

In the surface-emitting laser 13, only the top surface of the protrusion 27P of the p-type semiconductor layer 27 is electrically connected to the conductive film 31 as described above. Therefore, a current flowing from the p-type electrode PE to the conductive film 31, the majority of which is supplied to the semiconductor structure layer EM through the protrusion 27P, which is a low-resistance region, flows to the n-type electrode NE. In other words, in the surface-emitting laser 13, the protrusion 27P of the p-type semiconductor layer 27 functions as a current constriction portion that limits a range of current supply such that the current does not spread further.

In the surface-emitting laser 13, a lower surface of the second multilayer reflector 33 faces the top surface of the first multilayer reflector 22 with the conductive film 31 and the semiconductor structure layer EM interposed therebetween. As a result, the first multilayer reflector 22 and the second multilayer reflector 33 constitute, between the first multilayer reflector 22 and the second multilayer reflector 33, an optical cavity OC whose optical cavity length direction is perpendicular to the semiconductor structure layer EM (vertical direction in FIG. 5).

When a voltage is applied to the n-type electrode NE and the p-type electrode PE and a current flows between the n-type electrode NE and the p-type electrode PE, the current flows through the light-emitting layer 24 of the semiconductor structure layer EM, and when the threshold current, which is a predetermined current value, is reached, an intensity of the blue light emitted from the light-emitting layer 24 increases rapidly.

The blue light emitted from the light-emitting layer 24 when the threshold current is reached undergoes repeated reflection between the first multilayer reflector 22 and the second multilayer reflector 33, that is, within the optical cavity OC, thereby reaching a resonant state (that is, laser oscillation).

In the surface-emitting laser 13, a reflectance for the blue light of the first multilayer reflector 22 is slightly lower than a reflectance for the blue light of the second multilayer reflector 33. Therefore, a portion of the blue light that has resonated in the optical cavity OC is transmitted through the first multilayer reflector 22 and the transparent substrate 21 and is emitted downward in FIG. 5. In other words, a bottom surface of the transparent substrate 21 constitutes the light-emitting surface of the surface-emitting laser 13.

An antireflection film AR, in which Nb₂O₅ and SiO₂ are stacked, is formed on the bottom surface of the transparent substrate 21. The antireflection film AR is a so-called AR coating that suppresses reflection, by the transparent substrate 21, of the blue light emitted from the transparent substrate 21 upward in FIG. 5.

In the light-emitting device 100 of this embodiment, each of the n-type electrode NE and the p-type electrode PE of the surface-emitting laser 13 is bonded to a bottom of the recess of the substrate 11 via a conductive adhesive member (not illustrated), such that the top surface of the second multilayer reflector 33 of the surface-emitting laser 13 is opposed to the bottom of the recess of the substrate 11. Accordingly, when the surface-emitting laser 13 is mounted on the bottom of the recess of the substrate 11, the light is emitted upward from the surface-emitting laser 13.

### Photodetector 15

Refer again to FIG. 1 and FIG. 2. The photodetector 15 is an element having a rectangular top-surface shape and is mounted on the bottom surface of the recess of the substrate 11, spaced apart from the surface-emitting laser 13. The photodetector 15 is a photodiode (PD) that receives a light emitted from the outside and generates an electrical signal corresponding to an intensity of the received light. The photodetector 15 is mounted, for example, by a method employing surface mounting or wire bonding.

### Transmissive Plate 17

The transmissive plate 17 is a transparent, flat plate-like body having a rectangular top-surface shape. The transmissive plate 17 is bonded to a top surface of a frame portion forming the recess of the substrate 11 via an adhesive member AM. In other words, the transmissive plate 17 closes an opening of the recess of the substrate 11 so as to seal the surface-emitting laser 13 and the photodetector 15. In the light-emitting device 100 of this embodiment, the transmissive plate 17 is formed of a material having transmissive properties to the blue light, such as SiO₂.

The transmissive plate 17 may have, on the top surface, an optical component, such as a diffractive optical element (DOE) or a holographic optical element (HOE), which controls the beam pattern of the laser light.

### Light-reflecting Structure 19

The light-reflecting structure 19 has a rectangular top-surface shape and is a light-reflecting film formed on a lower surface of the transmissive plate 17. In the light-emitting device 100 of this embodiment, as illustrated in FIG. 1, the light-reflecting structure 19 is formed so as to cover a region on the right side of the region in which the surface-emitting laser 13 on the bottom surface of the recess of the substrate 11 is disposed.

In the light-emitting device 100 of this embodiment, the light-reflecting structure 19 is formed of a metal having a high reflectivity for the blue light, such as silver (Ag), Al, and chromium (Cr). The light-reflecting structure 19 is formed, for example, by using a sputtering method or a vapor deposition method to deposit a metal film serving as a material for the light-reflecting structure 19.

The light-reflecting structure 19 is formed so as not to block a region of the transmissive plate 17 where a main light ML emitted from the surface-emitting laser 13 is incident. Specifically, in a top view of the light-emitting device 100 as viewed from above, a distance from the central axis CA of the surface-emitting laser 13 to a long side of the light-reflecting structure 19 on the surface-emitting laser 13 side is preferably about 40 μm, for example.

### Emitted Light from Surface-Emitting Laser 13

The light emitted from the surface-emitting laser 13 of the light-emitting device 100 in this embodiment is described below using FIGS. 2, 5, and 6. In the surface-emitting laser 13 of this embodiment, as described above, the diameter Wₐ of the protrusion 27P of the p-type semiconductor layer 27 is smaller than the diameter W_{b} of the second multilayer reflector 33.

By virtue of the surface-emitting laser 13 having such a configuration and being a VCSEL made of a group III-nitride semiconductor, it has newly been found by the inventors of the present invention that, as illustrated in FIG. 2, there exist, in the laser light emitted from the surface-emitting laser 13, the main light ML (solid line in the figure) emitted along the central axis CA by resonance in the optical cavity OC, and, separately from the main light ML, a secondary light SL (dash-dot line in the figure) emitted at an angle θ with respect to the central axis CA. In other words, the secondary light SL is a laser light that is emitted in a direction different from that of the main light ML and that has a different optical axis, and is the laser light that is emitted separately from the main light ML.

The main light ML and the secondary light SL have different light outputs, but the peak wavelengths are identical. This secondary light SL is characteristic light generated from a VCSEL in which the diameter Wₐ of the protrusion 27P of the p-type semiconductor layer 27 is smaller than the diameter W_{b} of the second multilayer reflector 33 and which is formed of a material having a hexagonal crystal system, such as a group III-nitride semiconductor. Accordingly, for example, in VCSELs constituted of materials of the cubic crystal system, such as gallium arsenide (GaAs) and aluminum indium gallium phosphide (AlInGaP), which emit wavelengths in the red band, confirmation of the occurrence of the secondary light SL has not been obtained.

The secondary light SL is considered to be diffracted light in which a portion of the light resonating inside the optical cavity OC is diffracted at a predetermined angle toward a direction outside the optical cavity OC and toward the second multilayer reflector 33, and this diffracted light is emitted to the outside.

More specifically, the secondary light SL is considered to be a portion of the light that has reached a resonant state in the resonator OC, which proceeds from the p-type semiconductor layer 27 into the insulating layer 29 having a refractive index different from that of the p-type semiconductor layer 27, passes through the insulating layer 29, is reflected by the second multilayer reflector 33, and is then emitted to the outside of the surface-emitting laser 13 at a predetermined angle with respect to the central axis CA.

The main light ML emitted from the surface-emitting laser 13 forms a circular beam spot. The secondary light SL emitted from the surface-emitting laser 13 is emitted into a circular annular region surrounding the main light ML.

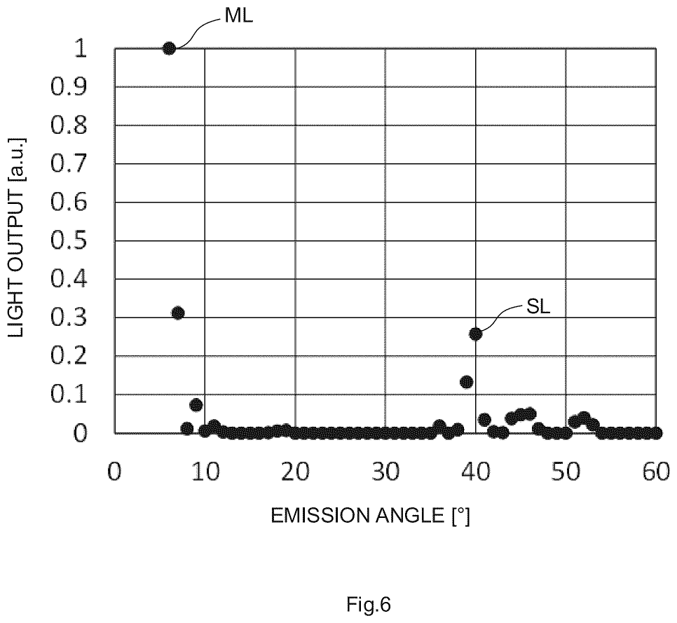

FIG. 6 is a graph showing the relationship between the light output and the emission angle of the light emitted from the surface-emitting laser 13 in this embodiment. In FIG. 6, the light output for each angle relative to the central axis CA is illustrated, with the light output of the main light ML of the surface-emitting laser 13 in the vicinity of an emission angle of 6° set to 1. Although the actual peak light output of the main light ML occurs at an emission angle of 0° (in other words, the light output at an emission angle of 0° is greater than the light output at emission angles other than 0°), here, although not illustrated, the light output at an emission angle of around 6° is set to 1.

The light emitted from the surface-emitting laser 13 in this embodiment includes, in addition to the main light ML, a light component that has an angle of about 40° with respect to the central axis CA and a light output of about 1% of the peak of the light output of the main light ML. In the surface-emitting laser 13 of this embodiment, the light component at this angle θ=40° is emitted as the secondary light SL.

The light component along the central axis CA of the light transmitted through the protrusion 27P is eventually emitted from the surface-emitting laser 13 as the main light ML. On the other hand, a portion of the light component at an angle to the central axis CA is incident on the second multilayer reflector 33 and is reflected by the second multilayer reflector 33.

At this time, the light components that are incident on the second multilayer reflector 33 at an angle θ satisfying W_{b} sinθ=mλ (where the emission wavelength is λ and m is an integer) become lights whose phases are aligned with one another upon reflection by the second multilayer reflector 33.

Accordingly, in the surface-emitting laser 13 of this embodiment, the secondary light SL as the laser light is emitted in a direction at an angle θ. In the surface-emitting laser 13 of this embodiment, the angle θ is approximately 40°, as described in the foregoing description.

Refer again to FIG. 1 and FIG. 2. In this embodiment of the light-emitting device 100, the light-reflecting structure 19 is formed so as to cover a portion of the circular annular region on the bottom surface of the transmissive plate 17 onto which the secondary light SL is irradiated. Accordingly, a part of the secondary light SL emitted from the surface-emitting laser 13 is reflected by the light-reflecting structure 19.

In the light-emitting device 100 of this embodiment, the photodetector 15 is mounted at a position on the bottom surface of the recess of the substrate 11 where the secondary light SL reflected by the light-reflecting structure 19 can be received. As a result, the photodetector 15 generates an electrical signal corresponding to a light intensity of the received secondary light SL.

Thus, for example, when the photodetector 15 receives the secondary light SL and the light intensity of the received secondary light SL is less than a predetermined value, an adjustment such as increasing the light output of the surface-emitting laser 13 can be made. In other words, according to the light-emitting device 100 of this embodiment, the light output of the surface-emitting laser 13 can be controlled by monitoring the light intensity of the secondary light SL. At this time, since the peak light output of the secondary light SL has a relationship of about 1% to the peak light output of the main light ML, the light intensity of the secondary light SL can be monitored to control the main light ML.

Thus, according to the light-emitting device 100 in this embodiment, the light emitted from the surface-emitting laser 13, which is a vertical-cavity light-emitting element, includes the main light ML and the secondary light SL, and the output of the emitted light of the surface-emitting laser 13 can be controlled by acquiring the light intensity of the secondary light SL via the photodetector 15.

In the light-emitting device 100 of this embodiment, in order for the secondary light SL to be emitted from the surface-emitting laser 13, for a light having a peak wavelength of 445 nm, the diameter Wₐ of the protrusion 27P of the p-type semiconductor layer 27 is preferably less than 10 μm, and the diameter W_{b} of the second multilayer reflector 33 is preferably 10 μm or more and 20 μm or less.

In the light-emitting device 100 of this embodiment, the light-reflecting structure 19 need only have a configuration capable of reflecting the secondary light SL, and need not be a metal reflective film. For example, the light-reflecting structure 19 may be constituted of a dielectric multilayer film formed by stacking a plurality of dielectric films.

In the light-emitting device 100 of this embodiment, it has been described that the surface-emitting laser 13 includes an insulating layer 29 that covers from the top surface of the p-type semiconductor layer 27, excluding the protrusion 27P, to the side surface of the n-type semiconductor layer 23, excluding the lower portion 23A. However, the insulating layer 29 need not necessarily be formed, as long as the formation region of the insulating layer 29 functions as an insulating portion.

The outer region of the top surface of the p-type semiconductor layer 27, which is outside of the protrusion 27P, is formed by dry etching, for example. At this time, the outer region is in an electrically inactive state due to etching damage, that is, it is a high-resistance region having a higher electrical resistance than the protrusion 27P. Accordingly, even without forming the insulating layer 29 on the outer region, the outer region functions as an insulating portion.

### Application Example of Light-Emitting Device 100

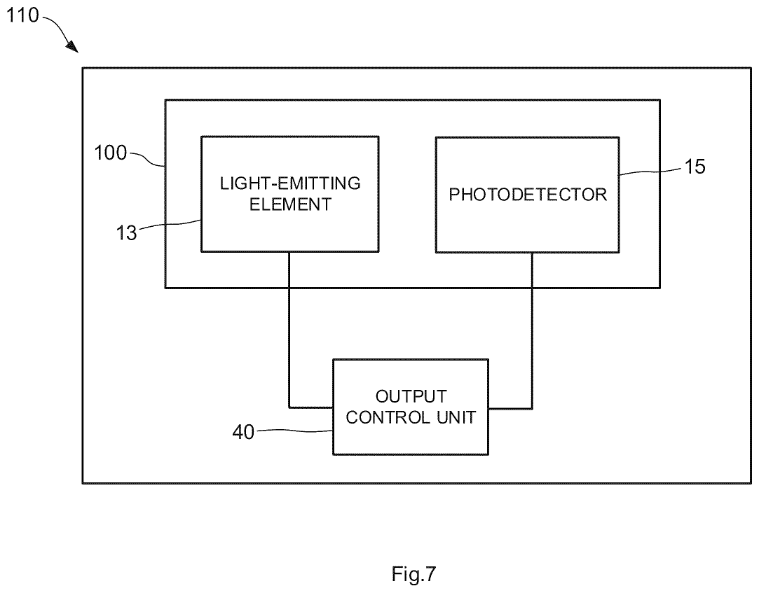

Here, an application example of the light-emitting device 100 will be described using FIG. 7. FIG. 7 is a block diagram illustrating a configuration of a light-emitting module 110 according to an application example of the light-emitting device 100. The light-emitting module 110 includes the above-described light-emitting device 100 and an output control unit 40.

The output control unit 40 is a control unit electrically connected to each of the surface-emitting laser 13 and the photodetector 15 of the light-emitting device 100. The output control unit 40 is, for example, an automatic power control (APC) circuit that automatically adjusts a drive current of the surface-emitting laser 13 such that the light output of the surface-emitting laser 13 remains constant.

In the light-emitting module 110 of this embodiment, the output control unit 40 acquires, from the photodetector 15, an electrical signal corresponding to the light intensity of the secondary light SL, and adjusts the drive current of the surface-emitting laser 13 based on the acquired electrical signal. This can eliminate the need to manually adjust the light output of the surface-emitting laser 13 according to the light intensity of the secondary light SL received by the photodetector 15, for example.

### Modification 1

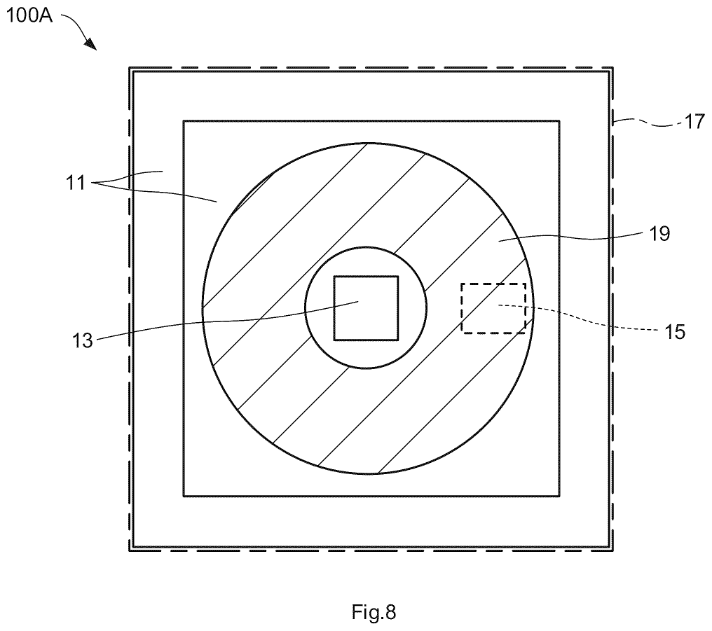

Next, Modification 1 of the light-emitting device 100 of Embodiment 1 is described using FIG. 8. FIG. 8 is a top view of a light-emitting device 100A according to Modification 1. The light-emitting device 100A is similar to the light-emitting device 100 in all other respects, except that the light-reflecting structure 19 is formed in a different manner from that in Embodiment 1.

In the light-emitting device 100A of this modification, the light-reflecting structure 19 has a circular annular shape in the top-surface shape and is formed so as to cover the entire circular annular region of the transmissive plate 17 where the secondary light SL is incident. Accordingly, all of the secondary light SL emitted from the surface-emitting laser 13 is reflected by the light-reflecting structure 19.

In this modification of the light-emitting device 100A, with this configuration, it is possible to suppress leakage of the secondary light SL to the outside of the surface-emitting laser 13. That is, it is possible to suppress the light other than the main light ML from being emitted by the light-emitting device 100A.

### Modification 2

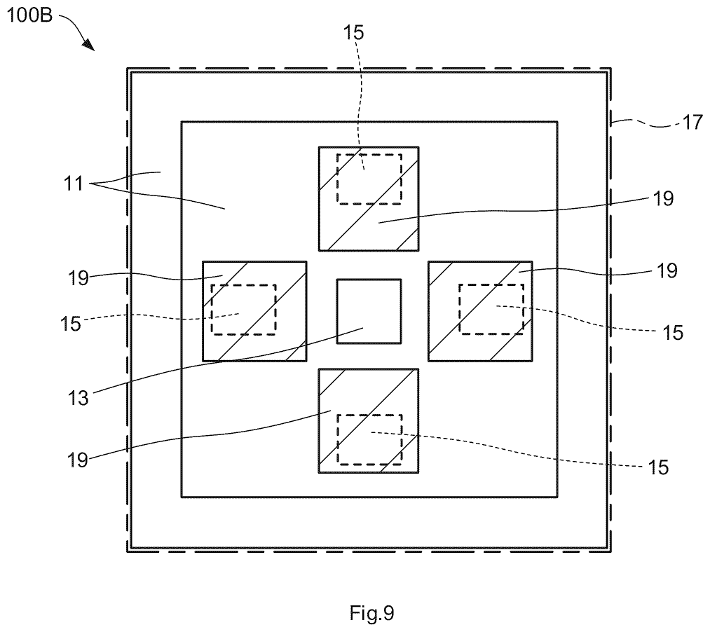

Next, Modification 2 of the light-emitting device 100 of Embodiment 1 will be described using FIG. 9. FIG. 9 is a top view of a light-emitting device 100B according to Modification 2. The light-emitting device 100B is similar to the light-emitting device 100 in other respects, except that a manner of forming the light-reflecting structure 19 differs from Embodiment 1.

In the light-emitting device 100B according to this modification, the light-reflecting structures 19 have a rectangular top-surface shape and, in a top view, are formed at four locations of above, below, left, and right of the surface-emitting laser 13. In the light-emitting device 100B of this modification, four photodetectors 15 are provided, in top view, at the top, bottom, left, and right such that each can receive the secondary light SL reflected by each of the light-reflecting structures 19.

In the light-emitting device 100B of this modification, the light intensity of the secondary light SL is acquired from each of the plurality of photodetectors 15, whereby the intensity of the secondary light SL can be acquired more accurately than, for example, when only one photodetector 15 is used.

### Modification 3

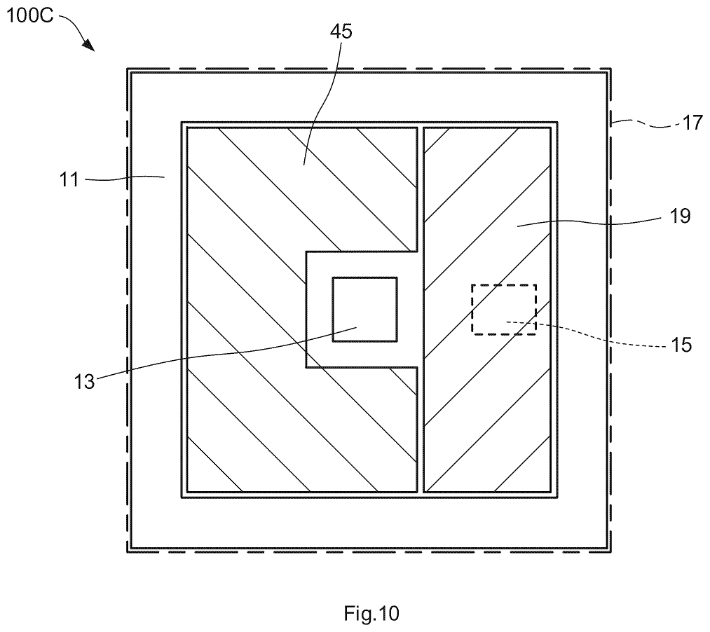

Next, Modification 3 of the light-emitting device 100 of Embodiment 1 is described using FIG. 10. FIG. 10 is a top view of a light-emitting device 100C according to Modification 3. The light-emitting device 100C differs from Embodiment 1 in that it includes a light-absorbing structure 45 and is otherwise similar to the light-emitting device 100.

The light-absorbing structure 45 is a light-absorbing film formed, on the transmissive plate 17, in a region excluding the region where the main light ML is incident and the formation region of the light-reflecting structure 19. The light-absorbing structure 45 is formed, for example, by depositing metal nanoparticles or oxide films with light-absorbing properties on the transmissive plate 17. In particular, metal nanoparticles such as Ag nanoparticles with a diameter of about 100 nm or less can be used, and more preferably, metal nanoparticles with a diameter of about 70 nm can be used to efficiently absorb the light in the blue wavelength range.

In this modification of the light-emitting device 100C, this configuration allows only the main light ML to be emitted from the light-emitting device 100C. Since the light-absorbing structure 45 can absorb the secondary light SL that does not contribute to the light reception in the recess of the substrate 11, a noise reduction effect is expected, and the intensity of the secondary light SL can be acquired more accurately.

### Embodiment 2

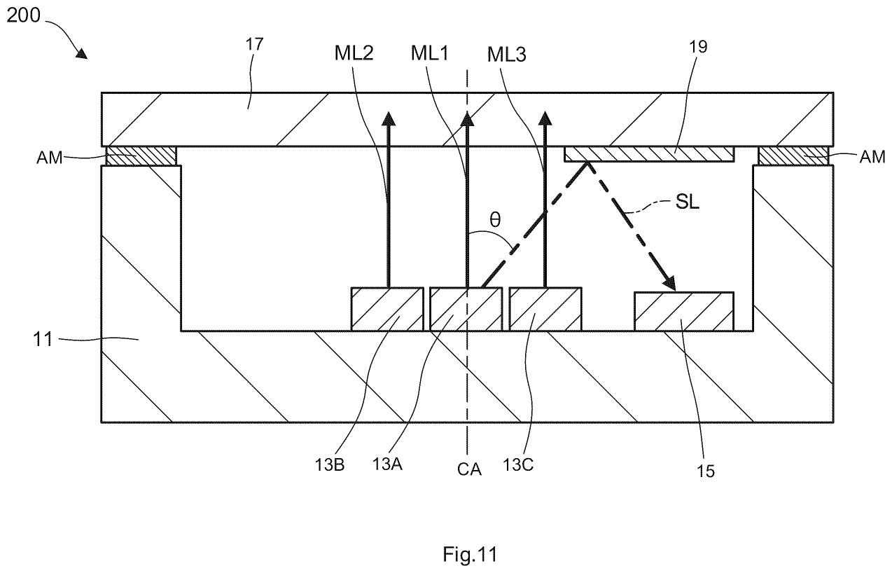

Next, with reference to FIG. 11, a light-emitting device 200 according to Embodiment 2 will be described. FIG. 11 is a cross-sectional view of the light-emitting device 200. In one respect, the light-emitting device 200 differs from Embodiment 1, namely that it includes a plurality of vertical-cavity light-emitting elements, and in other respects it is similar to the light-emitting device 100.

In the light-emitting device 200 of this embodiment, three surface-emitting lasers 13A, 13B, and 13C are mounted on the bottom surface of the recess in the substrate 11. In the light-emitting device 200 of this embodiment, the surface-emitting laser 13A emits blue light including a main light ML1 and a secondary light SL, as in Embodiment 1.

In the light-emitting device 200 of this embodiment, the surface-emitting laser 13B emits a main light ML2 at a red color wavelength. In the light-emitting device 200 of this embodiment, the surface-emitting laser 13C emits a main light ML3 having a green wavelength. Therefore, the light-emitting device 200 in this embodiment emits a white light mixed with a blue light, a red light, and a green light.

In the light-emitting device 200 of this embodiment, the light output of the surface-emitting laser 13A can also be adjusted by receiving, with the photodetector 15, the secondary light SL emitted from the surface-emitting laser 13A and by monitoring the light intensity of the received secondary light SL. The light output of the surface-emitting laser 13B and the surface-emitting laser 13C can also be adjusted in accordance with the adjustment.

In the light-emitting device 200 of this embodiment, the surface-emitting laser 13C may be capable of emitting the secondary light SL. In other words, a plurality of photodetectors 15 may be used to monitor a plurality of wavelengths of the secondary light SL.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2025-006812 filed on Jan. 17, 2025, the entire contents of which are incorporated herein by reference.

### DESCRIPTION OF REFERENCE SIGNS

100, 100A, 100B, 100C, 200 Light-emitting device
11 Substrate
13 Surface-emitting laser (vertical-cavity light-emitting element)
15 Photodetector
17 Transmissive Plate
19 Light-Reflecting Structure
21 Transparent Substrate
22 First multilayer reflector
23 n-type semiconductor layer
24 Light-emitting layer
25 Intermediate layer
26 Electron blocking layer
27 p-type semiconductor layer
29 Insulating layer
31 Conductive film
33 Second multilayer reflector
40 Output control unit
45 Light-absorbing structure
NE n-type electrode
PE p-type electrode

What is claimed is:

1. A light-emitting device comprising:
a substrate having a recess;
a vertical-cavity light-emitting element mounted on a bottom surface of the recess of the substrate and including a group III-nitride semiconductor, the vertical-cavity light-emitting element emitting a laser light toward an opening of the recess, the laser light including a main light forming a beam spot and a secondary light, the secondary light being emitted in a direction different from the main light and having a lower light output than the main light;
a photodetector mounted on a bottom surface of the recess of the substrate;
a transmissive plate sealing an opening of the recess; and
a light-reflecting structure formed in a region of the transmissive plate, the region being other than a main light incident region as a region where the main light is incident.

2. The light-emitting device according to claim 1, wherein
the light-reflecting structure is formed at least partially in a region where the secondary light is incident on the transmissive plate.

3. The light-emitting device according to claim 2, wherein
the light-reflecting structure is formed annularly in the transmissive plate so as to surround the main light incident region.

4. The light-emitting device according to claim 1, comprising
a light-absorbing film formed over a region of the transmissive plate other than a formation region of the main light incident region and the light-reflecting structure.

5. The light-emitting device according to claim 1, wherein
the vertical-cavity light-emitting element includes:
a transparent substrate;
a first multilayer reflector formed on the transparent substrate;
a semiconductor structure layer including a first semiconductor layer, a light-emitting layer, and a second semiconductor layer, the first semiconductor layer being made of a semiconductor having a first conductivity type formed on the first multilayer reflector, the light-emitting layer being formed on the first semiconductor layer, the second semiconductor layer having a second conductivity type opposite to the first conductivity type formed on the light-emitting layer; and
a second multilayer reflector formed on the semiconductor structure layer and constituting an optical cavity between the first multilayer reflector and the second multilayer reflector, wherein
the vertical-cavity light-emitting element is mounted such that a bottom surface of the recess faces a top surface of the second multilayer reflector, and
the semiconductor structure layer has an insulating portion formed in an annular region in top view, and a region surrounded by the annular region is located in a region inside an outer edge of the second multilayer reflector in top view.

6. The light-emitting device according to claim 5, wherein
the insulating portion has a transmissive insulating layer formed in the annular region, and
a refractive index of the second semiconductor layer is greater than a refractive index of the insulating layer.

7. The light-emitting device according to claim 1, comprising
a plurality of vertical-cavity light-emitting elements emitting lights having mutually different wavelengths, and
at least one of the plurality of vertical-cavity light-emitting elements emits the secondary light.

8. A light-emitting device comprising:
a substrate having a recess;
a vertical-cavity light-emitting element made of a group III-nitride semiconductor mounted on a bottom surface of the recess of the substrate;
a photodetector mounted on a bottom surface of the recess of the substrate;
a transmissive plate sealing an opening of the recess; and
a light-reflecting structure formed in a region of the transmissive plate, the region being other than a main light incident region as a region where a main light emitted from the vertical-cavity light-emitting element to form a beam spot is incident, wherein
the vertical-cavity light-emitting element includes:
a transparent substrate;
a first multilayer reflector formed on the transparent substrate;
a semiconductor structure layer including a first semiconductor layer, a light-emitting layer, and a second semiconductor layer, the first semiconductor layer being made of a semiconductor having a first conductivity type formed on the first multilayer reflector, the light-emitting layer being formed on the first semiconductor layer, the second semiconductor layer having a second conductivity type opposite to the first conductivity type formed on the light-emitting layer; and
a second multilayer reflector formed on the semiconductor structure layer and constituting an optical cavity between the first multilayer reflector and the second multilayer reflector, wherein
the vertical-cavity light-emitting element is mounted such that a bottom surface of the recess faces a top surface of the second multilayer reflector, and
the semiconductor structure layer has an insulating portion formed in an annular region in top view, and a region surrounded by the annular region is located in a region inside an outer edge of the second multilayer reflector in top view.

9. A light-emitting module comprising:
a light-emitting device including: a substrate having a recess; a vertical-cavity light-emitting element mounted on a bottom surface of the recess of the substrate and including a group III-nitride semiconductor, the vertical-cavity light-emitting element emitting a laser light toward an opening of the recess, the laser light including a main light forming a beam spot and a secondary light, the secondary light being emitted in a direction different from the main light and having a lower light output than the main light; a photodetector mounted on a bottom surface of the recess of the substrate; a transmissive plate sealing an opening of the recess; and a light-reflecting structure formed in a region of the transmissive plate, the region being other than a main light incident region as a region where the main light is incident; and
an output control unit electrically connected to each of the vertical-cavity light-emitting element and the photodetector and capable of controlling an output of a laser light of the vertical-cavity light-emitting element, wherein
the output control unit controls the output of the laser light of the vertical-cavity light-emitting element in accordance with a light intensity received by the photodetector.
